(19) United States
(12) Patent Application Publication
(10) Pub. No.: US 2016/0240716 A1
(43) Pub. Date: Aug. 18, 2016

(54) ADDITIONAL FOUNDATION LAYER FOR THIN LAYER SOLAR CELLS

(71) Applicants: CHINA TRIUMPH INTERNATIONAL ENGINEERING CO., LTD., Shanghai (CN); CTF SOLAR GMBH, Dresden (DE)

(72) Inventors: Bastian SIEPCHEN, Dresden (DE); Shou PENG, Shanghai (CN)

(73) Assignees: China Triumph International Engineering Co., Ltd., Shanghai (CN); CTF Solar GmbH, Dresden (DE)

(21) Appl. No.: 14/915,126

(22) PCT Filed: Aug. 27, 2014
(86) PCT No.: PCT/EP2014/068194

§ 371 Date: May 3, 2016

(30) Foreign Application Priority Data
Aug. 30, 2013 (CN) 201310537497.6

(51) Int. Cl. H01L 31/073; H01L 31/0392; H01L 31/18; H01L 31/0216

(52) U.S. Cl. CPC H01L 31/073; H01L 31/02167; H01L 31/03925; H01L 31/1828

(57) ABSTRACT

The present invention concerns an improved method for the manufacture of CdTe thin-layer solar cells or a semi-finished product therefor, which provides for the application of an additional, adhesion-promoting layer which is applied to the front contact layer following its deposition in order to improve the growth of the subsequent CdS layer; it also concerns a thin-layer solar cell produced by said method. CdTe is a particularly preferred material for the adhesion-promoting layer, which is preferably a monolayer.

The present invention relates to an improved method for the manufacture of CdTe thin-layer solar cells or a semi-finished product therefor which provides for the application of an additional foundation layer which is applied to the front contact layer after the latter has been applied in order to improve growth of the subsequent CdS layer, and to a thin-layer solar cell produced by said method.

When manufacturing thin-layer solar cells of the prior art, a transparent front contact layer (for example TCO—transparent conducting oxide) is applied to a substrate, usually glass. A layer of pure or modified CdS (cadmium sulphide) is deposited on this front contact layer, followed by the layer of CdTe (cadmium telluride). Finally, the back contact layer is applied.

In the prior art, the CdS layer is applied using the CSS process (closed space sublimation), in which the glass substrate with the prepared front contact layer is moved over a crucible containing CdS. This crucible is heated and the material to be sublimated (CdS) is evaporated (sublimated) from the crucible and condenses on the front contact layer of the substrate, which is at a lower temperature than that of the crucible.

Closer investigations have shown that the CdS, which is present in the crucible as a granulate, decomposes into its components upon sublimation (2 CdS→2Cd+S₂). These components reach the surface of the front contact layer separately and thereupon bond together again to form CdS.

The subsequent application of the CdTe layer is also preferably carried out by means of the CSS process.

Finally, the back contact is applied, preferably as a sequence of layers.

In the process described and also below, the purification, tempering and sealing steps employed are as described in the prior art and will not be explained in any further detail. Similarly, the application of antireflective and protective layers (for example the back laminate or glass) will be as has been described.

In large-scale applications, the CdS and CdTe layers are applied by moving the substrates with prepared front contact layer (which faces the crucible) at a constant speed over the crucible so that CdS and CdTe layers with a uniform thickness are formed. The prior art process is carried out in serially interconnected heated vacuum chambers through which the substrates are moved on a conveying system formed by rollers or conveyor belts which support the substrates at their lateral edges.

In this process, care is taken to keep the CdS layer as thin as possible in order to limit deterioration of the optical properties of the solar cells by this layer. At the same time, however, it must be ensured that the CdS layer does not contain any voids (pin-holes) through which short-circuits between the front contact and the CdTe layer might occur. In accordance with the prior art, in order to satisfy these two requirements, a CdS layer thickness of 80 nm to 200 nm is preferred.

The disadvantage with manufacturing the CdS layer is that this layer grows very slowly, because the CdS or its components does not come out of the vapour and remain adhered to the surface of the front contact layer very easily. As a result, more CdS material has to be evaporated from the crucible as is required to construct the layer. In addition to the increased costs, this leads to increased deposition of CdS at sites where this is unwanted.

These problems give rise to a need to reduce the thickness of the CdS layer without losing quality and to utilise the CdS better, in particular in the CSS process. Furthermore, this should also accelerate the coating process.

This need is satisfied by means of a method in accordance with claim 1 of the invention. Advantageous implementations of the method are defined in the dependent claims. The thin-layer solar cell constituted in accordance with the invention is disclosed in claim 4. Advantageous embodiments of this thin-layer solar cell are defined in the dependent claims.

The method in accordance with the invention provides for the application of an adhesion-promoting layer on the front contact layer of the thin-layer solar cell, which adhesion-promoting layer both increases the deposition rate for the CdS and also improves the homogeneity of the deposited CdS layer.

The purpose of the adhesion-promoting layer is to extend the length of time that the Cd and/or S atoms (which are obtained from the S₂ molecules) remain on the surface of the front contact layer, and thus to increase the probability of reaction to form CdS.

Preferably, the adhesion-promoting agent is a thin layer of cadmium telluride (CdTe), tellurium (Te), selenium (Se) or cadmium selenide (CdSe) or mixtures of these elements or compounds. The term “mixture” in this context means that at least 10% of the adhesion-promoting layer consists of one or more of the elements or compounds mentioned. More particularly preferably, CdTe is used with the same grade of purity as that used for the photovoltaically active layer.

Preferably, the adhesion-promoting agent is applied as a thin layer, particularly preferably as a monolayer. In this manner, at the commencement of application of the CdS layer, the thickness of the layer is preferably less than 10 nm, particularly preferably less than 1 nm, and particularly preferably it is a monolayer (a single-atom or monomolecular layer). An adhesion-promoting layer which is too thick will have a negative influence on the optical properties of the CdS layer.

Investigations have shown that nucleation of the CdS layer on this adhesion-promoting layer is more homogeneous than with prior art methods. Thus, it is possible to reduce the thickness of the CdS layer. Advantageously, thicknesses in the range from 30 nm up to 100 nm may be obtained for the layers without the CdS layer exhibiting pin-holes. Advantageously again, the efficiency of the solar cells can thus be increased.

Measurements have shown that by using the adhesion-promoting layer, the deposition rate for CdS can be increased three-fold compared with the method without an adhesion-promoting layer.

The adhesion-promoting layer may be applied using prior art processes. Preferably, wet chemical processes or sputtering are used.

More particularly preferably, an adhesion-promoting layer (preferably a CdTe layer) is used, which advantageously may also be applied using the CSS process. In this regard, and advantageously, prior art units may be used. In the sequence of units in this regard, a first crucible is simply provided, over which the substrate coated with the front contact layer is initially moved. The adhesion-promoting layer is produced in this manner.

Investigations have shown that in the CSS process, adsorption and desorption seek equilibrium. This is a function of the substrate temperature (or more precisely the temperature of the layer applied by sublimation). By adjusting the substrate temperature, then, the target thickness of the layer can be obtained by means of a self-regulating process. This target layer thickness should preferably be less than 10 nm, and particularly preferably a monolayer, when coating with CdS is commenced.

After applying the layer of pure or modified CdS to the adhesion-promoting layer, further processing of the semi-finished product which is thus obtained may be carried out using prior art methods in order to produce the finished solar cell. In this manner, the CdTe layer, for example, and the back contact sequence of layers may be applied using known processes. In addition, variations and additional layers over the layer of pure or modified CdS are possible and are not affected by the use of the adhesion-promoting layer in accordance with the invention.

### FIGURES

FIG. 1 diagrammatically shows the configuration of the layers of a solar cell in accordance with the invention. The front contact (21) is applied to the glass substrate (1). Over the front contact is a thin adhesion-promoting layer (5) on which is the sequence of layers which is known in the art, consisting of the CdS layer (3), CdTe layer (4) and the back contact layer (22).

FIG. 2 diagrammatically shows a solar cell in accordance with the prior art. This shows a sequence of layers consisting of the front contact (21), CdS layer (3), CdTe layer (4) and back contact (22).

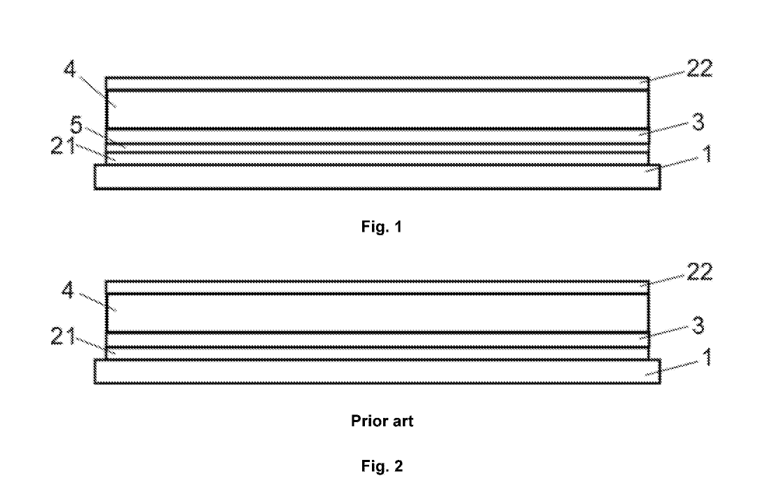

### EXEMPLARY EMBODIMENT

A substrate (1) with the dimensions (1600 mm×1200 mm×3.2 mm) was coated with a layer (21) of indium tin oxide (ITO) with a thickness of 250 nm as the transparent front contact layer (21).

Next, the substrate (1) was fed into a series of vacuum chambers with the front contact layer (21) directed downwards. The substrate (1) was heated to a temperature of 450° C. in the first vacuum chamber. This was carried out using appropriate heating means, while the substrate (1), resting on a conveyor device, was moved by it through the first vacuum chamber. The substrate (1) reached the next vacuum chamber and was then moved by the conveyor device (speed of movement 1.5 m/min) over a crucible containing granulated CdTe at a distance of 0.5 cm therefrom. The crucible extended over the entire width of the substrate (1) (perpendicular to the conveying direction) and in the conveying direction, it extended over a length of 17 cm. The CdTe in the crucible was heated to 620° C. and sublimated. The rising gases condensed on the front contact layer (21) of the substrate (1). Once the substrate (1) had passed the crucible, the front contact layer (21) had a complete (apart from at the contact points), homogeneous adhesion-promoting layer (5) with a thickness of 5 nm. After application of this adhesion-promoting layer (5), the substrate (1) was processed further as described in the prior art. In this regard, the substrate was heated further to 500° C. and conveyed into the subsequent treatment chambers. In this manner, the CdS layer (3) was applied, also using the CSS process. Because of the adhesion-promoting layer (5), this meant that this could be accomplished using fewer crucibles containing CdS. Thus, the substrate (1) was fed over only one crucible containing CdS (temperature: 640° C.). The thickness of the CdS layer which was obtained was 60 nm. Next, a 5000 nm thick layer of CdTe (4) was applied using the CSS process. Subsequently, the back contact layer (22) or layers were applied using prior art processes. The back contact layer here consisted of a sequence of an adaptive layer and an actual contact layer. Here, an adaptive layer formed from Te (50 nm) was formed by NP etching of the CdTe layer, onto which the Mo layer (250 nm) was subsequently deposited as the actual contact layer.

Finally, the further processing steps were carried out as described in the prior art.

### LIST OF REFERENCE NUMERALS

1 substrate (glass)
21 front contact (transparent, TCO)
22 back contact (metal)
3 CdS layer
4 CdTe layer
5 CdTe adhesion-promoting layer

1. A method for the manufacture of a semi-finished product for a thin-layer solar cell, characterized by the following steps:
a. providing a transparent substrate with a front contact layer or front contact sequence of layers
b. applying an adhesion-promoting layer to the front contact layer or front contact sequence of layers
c. applying a layer of pure or modified CdS to the adhesion-promoting layer.

2. The method as claimed in claim 1, wherein the layer of pure or modified CdS is applied using a CSS process.

3. The method as claimed in claim 2, wherein the steps b. and c. are carried out in a series of vacuum chambers with a common conveying system.

4. A thin-layer solar cell comprising at least the following layers:
a. a transparent substrate,
b. a front contact or front contact sequence of layers,
c. a layer of pure or modified CdS,
d. a CdTe layer,
e. a back contact or back contact sequence of layers,
wherein an adhesion-promoting layer is disposed between the front contact or front contact sequence of layers and the layer of pure or modified CdS.

5. The thin-layer solar cell as claimed in claim 4, wherein the adhesion-promoting layer comprises tellurium, cadmium telluride, selenium, cadmium selenide or mixtures thereof.

6. The thin-layer solar cell as claimed in claim 4, wherein the thickness of the adhesion-promoting layer is less than 10 nm.

7. The thin-layer solar cell as claimed in claim 4, wherein the adhesion-promoting layer is a monolayer.

8. The thin-layer solar cell as claimed in claim 5, wherein the thickness of the adhesion-promoting layer is less than 10 nm.

9. The thin-layer solar cell as claimed in claim 5, wherein the adhesion-promoting layer is a monolayer.
